(19) United States
(12) Patent Application Publication
(10) Pub. No.: US 2024/0092971 A1
(43) Pub. Date: Mar. 21, 2024

(54) FLUORINE-CONTAINING POLYETHER COMPOUND

(71) Applicants: DAIKIN INDUSTRIES, LTD., Osaka (JP); NATIONAL UNIVERSITY CORPORATION, IWATE UNIVERSITY, Morioka-shi (JP)

(72) Inventors: Yoshiyuki OISHI, Morioka-shi (JP); Tsuyoshi Noguchi, Osaka (JP)

(73) Assignees: DAIKIN INDUSTRIES, LTD., Osaka (JP); NATIONAL UNIVERSITYCORPORATION, IWATE UNIVERSITY, Morioka-shi (JP)

(21) Appl. No.: 18/505,260

(22) Filed: Nov. 9, 2023

Related U.S. Application Data
(63) Continuation of application No. PCT/JP22/19868, filed on May 10, 2022.

(30) Foreign Application Priority Data
May 10, 2021 (JP) 2021-079793

(51) Int. Cl. C08G 65/38

(52) U.S. Cl. CPC C08G 65/38

(57) ABSTRACT

The present disclosure provides a fluorine-containing polyether compound having a repeating unit represented by formula (1).

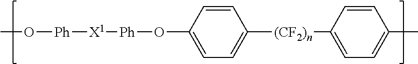

In formula (1), n represents an integer of 1 to 8, Ph represents a phenylene group, X¹ represents a heterocyclic ring or a hydrocarbon ring, one or both of two phenylene groups represented by Ph, and the heterocyclic ring or hydrocarbon ring represented by X¹ are optionally condensed with each other, and the phenylene group, the heterocyclic ring, and the hydrocarbon ring optionally have a substituent.

### CROSS-REFERENCE TO RELATED APPLICATIONS

This application is a Rule 53(b) Continuation of International Application No. PCT/JP2022/019868 filed May 10, 2022, which claims priority based on Japanese Patent Application No. 2021-079793 filed May 10, 2021, the respective disclosures of which are incorporated herein by reference in their entirety.

### TECHNICAL FIELD

The present disclosure relates to a fluorine-containing polyether compound.

### BACKGROUND ART

Non Patent Document 1 states that polymerization of 1,6-bis(4-fluorophenyl)perfluorohexane with bisphenol AF, bisphenol A, or resorcinol gives a poly(perfluoroalkylene aryl ether) having a particular structure.

### RELATED ART

### Non Patent Documents

Non Patent Document 1: Jeff W. Labadie, et al., “Perfluoroalkylene-Activated Poly(aryl ether) Synthesis,” Macromolecules, American Chemical Society, 1990, vol. 23, No. 26, 5371-5373

### SUMMARY

The present disclosure provides a fluorine-containing polyether compound having a repeating unit represented by formula (1).

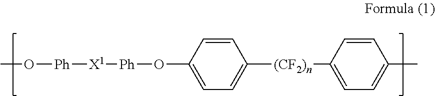

in formula (1), n represents an integer of 1 to 8, Ph represents a phenylene group, and X¹ represents a heterocyclic ring or a hydrocarbon ring; one or both of two phenylene groups represented by Ph, and the heterocyclic ring or the hydrocarbon ring represented by X¹ are optionally condensed with each other; and the phenylene group, the heterocyclic ring, and the hydrocarbon ring optionally have a substituent.

### Effects

The present disclosure may provide a fluorine-containing polyether compound that exhibits sufficiently low dielectric constant and dielectric dissipation factor and has both significantly high glass transition temperature and high solubility.

### DESCRIPTION OF EMBODIMENTS

Hereinafter, specific embodiments of the present disclosure will be described in detail, but the present disclosure is not limited to the following embodiments.

A fluorine-containing polyether compound of the present disclosure has a repeating unit represented by formula (1).

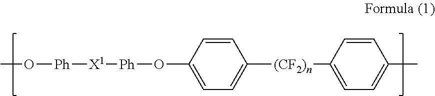

in formula (1), n represents an integer of 1 to 8, Ph represents a phenylene group, and X¹ represents a heterocyclic ring or a hydrocarbon ring; one or both of two phenylene groups represented by Ph, and the heterocyclic ring or the hydrocarbon ring represented by X¹ are optionally condensed with each other; and the phenylene group, the heterocyclic ring, and the hydrocarbon ring optionally have a substituent.

n represents an integer of 1 to 8. n is preferably an integer of 4 to 8, and is more preferably 4, 6, or 8.

Ph represents a phenylene group. In some embodiments, the phenylene group has a substituent but does not necessarily have a substituent. Examples of the substituent include halogen atoms, such as a fluorine atom; alkyl groups, such as a methyl group; and alkyl halide groups, such as a trifluoromethyl group.

X¹ represents a heterocyclic ring or a hydrocarbon ring. In some embodiments, the heterocyclic ring or hydrocarbon ring represented by X¹ is a ring having at least two bonding parts bonding to two phenylene groups; a ring having at least one bonding part bonding to at one of the two phenylene groups and at least one carbon-carbon bond shared with the other one of the two phenylene groups; or a ring having at least two carbon-carbon bonds shared with the two phenylene groups. The heterocyclic ring or hydrocarbon ring represented by X¹ is preferably a ring having at least two bonding parts bonding to the two phenylene groups, or a ring having at least one bonding part bonding to one of the two phenylene groups and at least one carbon-carbon bond shared with the other one of the two phenylene groups.

When the phenylene group represented by Ph and the ring represented by X¹ share at least one carbon-carbon bond, a structure represented by -Ph-X¹-Ph- includes a condensed ring formed by condensing the heterocyclic ring or hydrocarbon ring represented by X¹ and at least one of the phenylene groups represented by Ph. Accordingly, in the present disclosure, the phenylene group represented by Ph encompasses not only a residue produced by removing two hydrogen atoms from benzene but also a residue derived from benzene, obtained by removing one hydrogen atom from the benzene, and forming a part of a polycyclic ring by condensation with another ring. Examples of such a structure (structure represented by -Ph-X¹-Ph-) including a condensed ring includes a structure shown below.

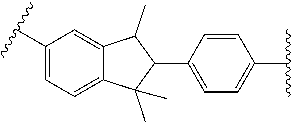 [SMILES: *c1ccc(C2C(C)c3cc(*)ccc3C2(C)C)cc1]

In the formula, each undulating line represents a bond position to an oxygen atom.

Among the rings represented by X¹, the heterocyclic ring is preferably a ring formed by carbon atoms and an atom or atoms other than a carbon atom. The atom other than the carbon atom is preferably a nitrogen atom, an oxygen atom, or sulfur atom, and more preferably a nitrogen atom. That is, the heterocyclic ring is preferably a nitrogen-containing heterocyclic ring. The number of atoms other than the carbon atom in the ring is preferably 1 to 3, and more preferably 3.

In some embodiments, the heterocyclic ring is an aliphatic heterocyclic ring or an aromatic heterocyclic ring. The heterocyclic ring is preferably an aromatic heterocyclic ring. Further, in some embodiments, the heterocyclic ring is a monocyclic ring or a polycyclic ring. The heterocyclic ring is preferably a monocyclic ring, more preferably a monocyclic aromatic heterocyclic ring, and still more preferably a monocyclic nitrogen-containing aromatic heterocyclic ring.

The number of members of the heterocyclic ring is not limited but is preferably 3 to 12, and more preferably 5 or more, and is more preferably 9 or less, and still more preferably 6 or less.

Examples of the heterocyclic ring include a furan ring, a thiophene ring, a pyrrole ring, an oxazole ring, an isoxazole ring, a thiazole ring, an isothiazole ring, an imidazole ring, a pyrazole ring, a 1,2,3-oxadiazole ring, a 1,2,4-oxadiazole ring, a 1,3,4-oxadiazole ring, a furazan ring, a 1,2,3-thiadiazole ring, a 1,2,4-thiadiazole ring, a 1,3,4-thiadiazole ring, a 1,2,3-triazole ring, a 1,2,4-triazole ring, a tetrazole ring, a pyridine ring, a pyridazine ring, pyrimidine ring, a pyrazine ring, and a triazine ring. Among others, the heterocyclic ring is preferably a 1,3,5-triazine ring.

In some embodiments, the heterocyclic ring has a substituent but does not necessarily have a substituent. Examples of the substituent include halogen atoms, such as a fluorine atom; alkyl groups, such as a methyl group; alkyl halide groups, such as a trifluoromethyl group; and aryl groups, such as a phenyl group.

In some embodiments, the hydrocarbon ring among the rings represented by X¹ is an aliphatic hydrocarbon ring or an aromatic hydrocarbon ring. In some embodiments, the aliphatic hydrocarbon ring is a saturated or unsaturated hydrocarbon ring not having aromaticity. In some embodiments, the hydrocarbon ring is a monocyclic ring or a polycyclic ring. In some embodiments, the polycyclic hydrocarbon ring is a condensed ring.

The carbon number of the hydrocarbon ring is preferably 3 to 30, more preferably 5 or more, and still more preferably 6 or more, and is more preferably 20 or less, and still more preferably 14 or less.

Examples of the hydrocarbon ring include monocyclic saturated hydrocarbon rings, such as a cyclopropane ring, a cyclobutane ring, a cyclopentane ring, a cyclohexane ring, a cycloheptane ring, a cyclooctane ring, a cyclononane ring, a cyclodecane ring, a cycloundecane ring, and a cyclododecane ring;
monocyclic non-aromatic unsaturated hydrocarbon rings, such as a cyclopropene ring, a cyclobutene ring, a cyclopropene ring, a cyclohexene ring, a cycloheptene ring, and a cyclooctene ring;
polycyclic non-aromatic hydrocarbon rings, such as a norbornene ring, a norbornadiene ring, a decahydronaphthalene ring, a bicycloundecane ring, and a spirobicyclopentane ring; and
aromatic hydrocarbon rings, such a benzene ring, a naphthalene ring, a phenanthrene ring, an anthracene ring, a fluorene ring, a tetracene ring, a chrysene ring, a pyrene ring, a pentacene ring, a benzopyrene ring, a triphenylene ring, a biphenyl ring, a diphenylmethane ring, a diphenyl ether ring, a diphenyl sulfone ring, and a diphenyl ketone ring.

In some embodiments, the hydrocarbon ring has a substituent but does not necessarily have a substituent. Examples of the substituent include halogen atoms, such as a fluorine atom; alkyl groups, such as a methyl group; alkyl halide groups, such as trifluoromethyl group; and aryl groups, such as a phenyl group.

The heterocyclic group or hydrocarbon group represented by X¹ is preferably at least one selected from the group consisting of rings represented by the following formulas.

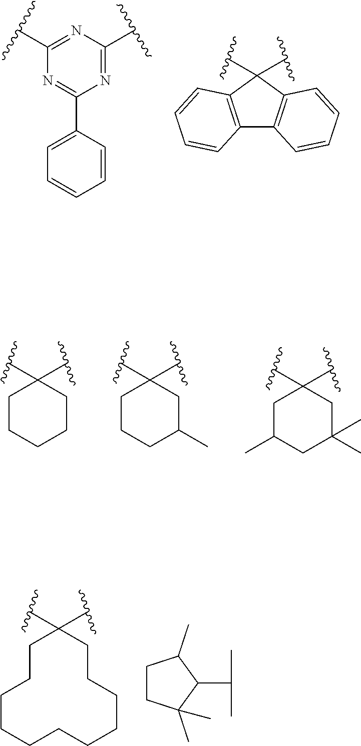

In each formula, each undulating line represents a bond position to the phenylene group represented by Ph, and a broken line represents a carbon-carbon bond shared with the phenylene group represented by Ph.

The fluorine-containing polyether compound having a repeating unit represented by formula (1) preferably has a glass transition temperature of 100 to 400° C., more preferably 110° C. or higher, and still more preferably 120° C. or higher, and more preferably 300° C. or lower, and still more preferably 250° C. or lower. The glass transition temperature is a value measured by thermomechanical analysis (TMA), differential scanning calorimetry (DSC), or dynamic viscoelasticity measurement (DMA).

In the fluorine-containing polyether compound having a repeating unit represented by formula (1), the average degree of polymerization of the repeating unit represented by formula (1) is preferably 500 or less, more preferably 400 or less, and still more preferably 300 or less, and is, in some embodiments, 2 or more, or 3 or more. The average degree of polymerization is determined by calculation from the number average molecular weight of the fluorine-containing polyether compound of the present disclosure.

The fluorine-containing polyether compound having a repeating unit represented by formula (1) preferably has a number average molecular weight (Mn) of 2,000 or higher, and more preferably 10,000 or higher, and preferably 500,000 or lower, and more preferably 300,000 or lower, in terms of standard polystyrene, the number average molecular weight measured by gel permeation chromatography (GPC).

The fluorine-containing polyether compound having a repeating unit represented by formula (1) preferably has a molecular weight distribution (Mw/Mn) of 2 or more, and preferably 5 or less, and more preferably 4 or less, in terms of standard polystyrene, the molecular weight distribution measured by gel permeation chromatography (GPC).

The fluorine-containing polyether compound having a repeating unit represented by formula (1) preferably has a logarithmic viscosity ηᵢₙₕ of 0.3 dL/g or higher, and more preferably 0.5 dL/g or higher. With regard to the logarithmic viscosity ηᵢₙₕ, the fluorine-containing polyether compound is dissolved in N-methyl-2-pyrrolidone (M4P) or the like as a solvent to prepare a solution whose solution concentration is 0.5 g/L, the solution viscosity of the resultant solution at 30° C. is measured, and the logarithmic viscosity ηᵢₙₕ may be calculated by the following formula.

Logarithmic viscosity ηᵢₙₕ=ln (solution viscosity/solvent viscosity)/solution concentration

The fluorine-containing polyether compound having a repeating unit represented by formula (1) may suitably be produced by polymerizing a dihydroxy compound (11) represented by formula (11) and an active aromatic compound (12) represented by formula (12).

HO-Ph-X¹-Ph-OH Formula (11):

wherein Ph and X¹ are the same as in formula (1).

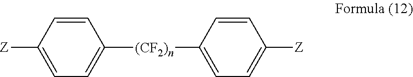

in formula (12), n is the same as in formula (1), and Z represents a halogen atom or a nitro group.

The polymerization of the dihydroxy compound (11) and the active aromatic compound (12) may be performed in the presence of a base. Examples of the base include carbonates, such as sodium carbonate, sodium hydrogen carbonate, potassium carbonate, potassium hydrogen carbonate, cesium carbonate, and cesium hydrogen carbonate; hydroxides, such as sodium hydroxide, potassium hydroxide, and cesium hydroxide; and fluoride compounds, such as sodium fluoride, potassium fluoride, and cesium fluoride.

The polymerization may be performed in a solvent. Examples of the solvent include N,N-dimethylformamide (DMF), N,N-dimethylacetamide (DMAc), N-methyl-2-pyrrolidone (NMP), tetramethylurea (TMU), 1,3-dimethyl-2-imidazolidone (DMI), N,N′-dimethylpropyleneurea (DMPU), dimethyl sulfoxide (DMSO), sulfolane, dimethyl sulfone, diphenyl sulfone, cyclopentanone, cyclohexanone, tetrahydrofuran (THF), and 1,4-dioxane.

To remove water produced by the polymerization of the dihydroxy compound (11) and the active aromatic compound (12) in the presence of a base, an azeotropic solvent, such as toluene, o-xylene, m-xylene, and p-xylene, is used in some embodiments.

The polymerization temperature is preferably 50 to 250° C., and more preferably 150 to 250° C. The polymerization time is preferably 0.1 to 50 hours, and more preferably 1 to 36 hours.

The average degree of polymerization of the repeating unit represented by formula (1) may be adjusted by changing the molar ratio of the dihydroxy compound (11) to the active aromatic compound (12), the polymerization temperature, the polymerization time, the concentration of the polymerization solution, and the others.

Further, the fluorine-containing polyether compound of the present disclosure has a repeating unit represented by formula (2).

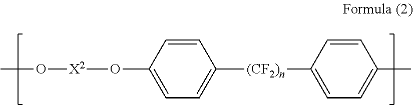

in formula (2), n represents an integer of 1 to 8, and X² represents a polycyclic aromatic hydrocarbon ring optionally having a substituent.
n represents an integer of 1 to 8. n is preferably an integer of 4 to 8, and more preferably 4, 6, or 8.
X² represents a polycyclic aromatic hydrocarbon ring. The polycyclic aromatic hydrocarbon ring is a ring formed by removing two hydrogen atoms from a polycyclic aromatic hydrocarbon obtained by condensing two or more aromatic rings, or a ring formed by removing two hydrogen atoms from a polycyclic aromatic hydrocarbon in which two or more aromatic rings are bonded by a single bond. In formula (2), the polycyclic aromatic hydrocarbon ring is directly bonded to two adjacent oxygen atoms.

The carbon number of the polycyclic aromatic hydrocarbon ring is preferably 8 to 30, more preferably 10 or more, and is more preferably 26 or less, and still more preferably 22 or less.

The number of rings of the polycyclic aromatic hydrocarbon ring is preferably 2 to 8, more preferably 6 or less, and still more preferably 5 or less.

Examples of the polycyclic aromatic hydrocarbon ring include a biphenyl ring, a terphenyl ring, a quaterphenyl ring, a naphthalene ring, a phenanthrene ring, an anthracene ring, a fluorene ring, a tetracene ring, a chrysene ring, a pyrene ring, a triphenylene ring, a pentacene ring, a benzopyrene ring, and a perylene ring.

Among these, the polycyclic aromatic hydrocarbon ring is preferably at least one selected from the group consisting of a biphenyl ring, a terphenyl ring, a quaterphenyl ring, a naphthalene ring, an anthracene ring, a tetracene ring, and a pentacene ring.

In some embodiments, the polycyclic aromatic hydrocarbon ring has a substituent but does not necessarily have a substituent. Examples of the substituent include halogen atoms, such as a fluorine atom; alkyl groups, such as a methyl group; alkyl halide groups, such as trifluoromethyl group; and aryl groups, such as a phenyl group.

The fluorine-containing polyether compound having a repeating unit represented by formula (2) preferably has a glass transition temperature of 96 to 400° C., more preferably 100° C. or higher, and preferably 300° C. or lower, and more preferably 250° C. or lower. The glass transition temperature is a value measured by thermomechanical analysis (TMA), differential scanning calorimetry (DSC), or dynamic viscoelasticity measurement (DMA).

In the fluorine-containing polyether compound having a repeating unit represented by formula (2), the average degree of polymerization of the repeating unit represented by formula (2) is preferably 500 or less, more preferably 400 or less, and still more preferably 300 or less, and is, in some embodiments, 2 or more, or 3 or more. The average degree of polymerization is determined by calculation from the number average molecular weight of the fluorine-containing polyether compound of the present disclosure.

The fluorine-containing polyether compound having a repeating unit represented by formula (2) preferably has a number average molecular weight (Mn) of 2,000 or higher, and more preferably 10,000 or higher, and preferably 500,000 or lower, and more preferably 300,000 or lower, in terms of standard polystyrene, the number average molecular weight measured by gel permeation chromatography (GPC).

The fluorine-containing polyether compound having a repeating unit represented by formula (2) preferably has a molecular weight distribution (Mw/Mn) of 2 or more, and preferably 5 or less, and more preferably 4 or less, in terms of standard polystyrene, the molecular weight distribution measured by gel permeation chromatography (GPC).

The fluorine-containing polyether compound having a repeating unit represented by formula (2) preferably has a logarithmic viscosity ηᵢₙₕ of 0.3 dL/g or higher, and more preferably 0.5 dL/g or higher. With regard to the logarithmic viscosity ηᵢₙₕ, the fluorine-containing polyether compound is dissolved in N-methyl-2-pyrrolidone (M4P) or the like as a solvent to prepare a solution whose solution concentration is 0.5 g/L, the solution viscosity of the resultant solution at 30° C. is measured, and the logarithmic viscosity ηᵢₙₕ may be calculated by the following formula.

Logarithmic viscosity ηᵢₙₕ=ln (solution viscosity/solvent viscosity)/solution concentration

The fluorine-containing polyether compound having a repeating unit represented by formula (2) may suitably be produced by polymerizing a dihydroxy compound (21) represented by formula (21) and an active aromatic compound (22) represented by formula (22).

HO—X²—OH Formula (21):

in formula (21), X² is the same as in formula (2).

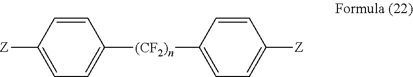

in formula (22), n is the same as in formula (2), and Z represents a halogen atom or a nitro group.

The polymerization of the dihydroxy compound (21) and the active aromatic compound (22) may be performed in the presence of a base. Examples of the base include carbonates, such as sodium carbonate, sodium hydrogen carbonate, potassium carbonate, potassium hydrogen carbonate, cesium carbonate, and cesium hydrogen carbonate; hydroxides, such as sodium hydroxide, potassium hydroxide, and cesium hydroxide; and fluoride compounds, such as sodium fluoride, potassium fluoride, and cesium fluoride.

The polymerization may be performed in a solvent. Examples of the solvent include N,N-dimethylformamide (DMF), N,N-dimethylacetamide (DMAc), N-methyl-2-pyrrolidone (NMP), tetramethylurea (TMU), 1,3-dimethyl-2-imidazolidone (DMI), N,N′-dimethylpropyleneurea (DMPU), dimethyl sulfoxide (DMSO), sulfolane, dimethyl sulfone, diphenyl sulfone, cyclopentanone, cyclohexanone, tetrahydrofuran (THF), and 1,4-dioxane.

To remove water produced by the polymerization of the dihydroxy compound (21) and the active aromatic compound (22) in the presence of a base, an azeotropic solvent, such as toluene, o-xylene, m-xylene, and p-xylene, is used in some embodiments.

The polymerization temperature is preferably 50 to 250° C., and more preferably 150 to 250° C. The polymerization time is preferably 0.1 to 50 hours, and more preferably 1 to 36 hours.

The average degree of polymerization of the repeating unit represented by formula (2) may be adjusted by changing the molar ratio of the dihydroxy compound (21) to the active aromatic compound (22), the polymerization temperature, the polymerization time, the concentration of the polymerization solution, and the others.

The fluorine-containing polyether compound of the present disclosure exhibits sufficiently low dielectric constant and dielectric dissipation factor and has both significantly high glass transition temperature and high solubility, and therefore it may suitably be used as a low dielectric material.

The fluorine-containing polyether compound of the present disclosure exhibits sufficiently low dielectric constant and dielectric dissipation factor and has both significantly high glass transition temperature and high solubility, and therefore it may suitably be used as a substrate for semiconductor package substrates, flexible printed circuit boards, rigid printed circuit boards, or the like.

The fluorine-containing polyether compound of the present disclosure exhibits sufficiently low dielectric constant and dielectric dissipation factor and has both significantly high glass transition temperature and high solubility, and therefore it may suitably be used as a material for semiconductor package wiring boards, flexible printed wiring boards, rigid printed wiring boards, TAB tapes, COF tapes, or metal wiring or the like; cover substrates for metal wiring or chip members such as IC chips; interlayer insulating films for liquid crystal displays, organic electroluminescence displays, electronic paper, solar cells; or electronic components or electronic devices, such as base substrates, adhesive sheets, prepregs, and primers.

The fluorine-containing polyether compound of the present disclosure has a low dielectric constant and a low dielectric loss at high frequencies in particular, and therefore may suitably be used as a material for electronic components or electronic devices using microwaves at high frequencies, microwaves of 3 to 30 GHz in particular. For example, the fluorine-containing polyether compound of the present disclosure may suitably be used as a material for insulating plates for high frequency circuits, insulating materials for connecting components, printed circuit boards, bases or antenna covers for high frequency vacuum tubes, or coated electric wire such as coaxial cables and LAN cables. Further, the fluorine-containing polyether compound of the present disclosure may suitably be used as a material for satellite communication devices or devices in cellular phone base stations, which use microwaves of 3 to 30 GHz.

Examples of the printed circuit board include, but not limited to, printed wiring boards for electronic circuits of cellular phones, various computers, communication devices, and the like.

Examples of the coaxial cable include, but not limited to, coaxial cables having a structure formed by stacking an internal conductor, an insulating coating layer, an external conductor layer, and a protective coating layer in order from the core to the outer periphery.

The fluorine-containing polyether compound of the present disclosure has a low dielectric constant and a low dielectric loss, has excellent heat resistance, solvent-solubility, electrically insulating properties, colorless and transparent characteristics, and flexibility, and is easily made into a thin film, and therefore it may suitably be used for interlayer insulating films, films, adhesive sheets, prepregs, primers, resist materials, and the like. Among these, the fluorine-containing polyether compound of the present disclosure is suitable for interlayer insulating films and films.

The film may be produced by forming the fluorine-containing polyether compound of the present disclosure by a known film forming method, such as an extrusion forming method, a calender forming method, and a solution casting method. Further, in some embodiments, a sand blast treatment, a corona treatment, a plasma treatment, or an etching treatment is performed on the film.

The embodiments have been described above, and it will be understood that various changes in the embodiments and details may be made without departing from the spirit and scope of the claims.

The present disclosure provides a fluorine-containing polyether compound having a repeating unit represented by formula (1).

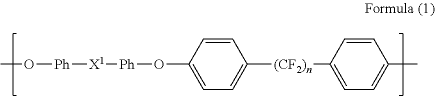

in formula (1), n represents an integer of 1 to 8, Ph represents a phenylene group, and X¹ represents a heterocyclic ring or a hydrocarbon ring; one or both of two phenylene groups represented by Ph, and the heterocyclic ring or the hydrocarbon ring represented by X¹ are optionally condensed with each other; and the phenylene group, the heterocyclic ring, and the hydrocarbon ring optionally have a substituent.

In formula (1), X¹ preferably represents an aromatic heterocyclic ring optionally having a substituent, an aromatic hydrocarbon ring optionally having a substituent, or an aliphatic hydrocarbon ring optionally having a substituent.

In formula (1), X¹ preferably represents at least one selected from the group consisting of rings represented by the following formulas.

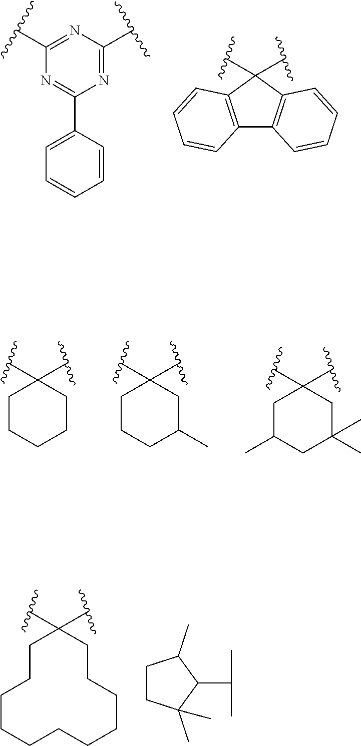

in each formula, each undulating line represents a bond position to the phenylene group represented by Ph, and a broken line represents a carbon-carbon bond shared with the phenylene group represented by Ph.

The average degree of polymerization of the repeating unit represented by formula (1) is preferably 2 to 300.

Moreover, the present disclosure provides a fluorine-containing polyether compound having a repeating unit represented by formula (2).

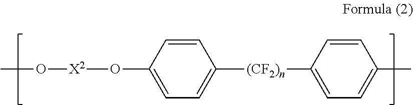

in formula (2), n represents an integer of 1 to 8, and X² represents a polycyclic aromatic hydrocarbon ring optionally having a substituent.

In formula (2), the polycyclic aromatic hydrocarbon ring is preferably at least one selected from the group consisting of a biphenyl ring, a terphenyl ring, a quaterphenyl ring, a naphthalene ring, an anthracene ring, a tetracene ring, and a pentacene ring.

The average degree of polymerization of the repeating unit represented by formula (2) is preferably 2 to 300.

Further, the present disclosure provides a low dielectric material containing the above fluorine-containing polyether compound.

Furthermore, the present disclosure may provide the present disclosure provides a semiconductor package substrate, a flexible printed circuit board, or a rigid printed circuit board containing the above fluorine-containing polyether compound.

### EXAMPLES

Next, the embodiments of the present disclosure will be described with reference to Examples, but the present disclosure is not limited to those Examples.

Numerical values in Examples were measured by the following methods.
(1) GPC: High Performance GPC system HLC-8220GPC manufactured by Tosoh Corporation (column: Tosoh TSKgel (α-M), column temperature: 45° C., detector: UV-8020, wavelength 254 nm, eluent: N-methyl-2-pyrrolidone (M4P) (containing 0.01 mol/L of lithium bromide), calibration curve: standard polystyrene, column flow rate: 0.2 mL/min)
(2) Infrared spectrum (FT-IR): FT/IR-4200 manufactured by JASCO Corporation
(3) Nuclear magnetic resonance spectrum (M4R): AC400P manufactured by BRUKER
(4) Thermogravimetric analysis (TGA): TG/DTA7300 manufactured by Hitachi High-Tech Science Systems Corporation, temperature-increasing rate 10° C./min
(5) Differential scanning calorimetry (DSC): DSC7000 manufactured by Hitachi High-Tech Science Systems Corporation, temperature-increasing rate 20° C./min
(6) Thermomechanical analysis (TMA): TMA7000 manufactured by Hitachi High-Tech Science Systems Corporation, temperature-increasing rate 10° C./min
(7) Dynamic viscoelasticity measurement (DMA): DMA7100 manufactured by Hitachi High-Tech Science Systems Corporation, temperature-increasing rate: 2° C./min
(8) Tensile test: Autograph AGS-D manufactured by SHIMADZU CORPORATION, tensile speed 1.0 mm/min
(9) Ultraviolet-visible spectrophotometer: UV-1800 manufactured by SHIMADZU CORPORATION
(10) Refractive index measurement: Metricon Model 2010/M PRISM COUPLER
(11) Dielectric constant measurement: Dielectric constant and dielectric dissipation factor measurement apparatus manufactured by AET, Inc. (cavity resonator type, 10 GHz, 20 GHz)

### Synthesis Example 1

Synthesis of 1,6-Bis(4-fluorophenyl)perfluorohexane (FPPFH) In a round-bottomed flask (100 mL) equipped with a stirring bar, a Dimroth condenser, and a nitrogen introducing tube, 1-fluoro-4-iodobenzene (1.25 mL, 10.8 mmol), dimethyl sulfoxide (DMSO, 15 mL), and 1,6-diiodoperfluorohexane (3.00 g, 5.42 mmol) were placed and dissolved. Thereafter, a copper powder (1.56 g, 24.4 mmol) was added thereto, the temperature of the resultant mixture was increased in stages to 120° C. in a nitrogen gas atmosphere, and the mixture was then stirred for 48 hours. After the mixture was left standing to cool to room temperature, the copper powder was removed by suction filtration, and DMSO was distilled away by reduced-pressure distillation. The residue was dissolved in diethyl ether, the resultant solution was subjected to suction filtration, and the filtrate was then washed with distilled water. An organic layer was taken out, and anhydrous sodium sulfate was added thereto to perform dehydration. Thereafter, the resultant was filtered to obtain a filtrate, and diethyl ether was distilled away from the filtrate to give a crude product. The crude yield was 1.73 g, 65%. Purification was performed by reduced-pressure distillation (100° C./0.17 Torr) to give a white crystalline product (yield 1.69 g, 64%).

Melting point: 40 to 41° C.

FT-IR (KBr, cm⁻¹): 1515 (C═C), 1243 (C—F)

¹H-NMR (DMSO-d₆, ppm): 7.73 (4H), 7.41 (4H)

¹³C-NMR (DMSO-d₆, ppm): 165.5, 163.5, 129.6, 129.5, 123.8, 116.6, 116.4

¹⁹F-NMR (DMSO-d₆, ppm): −107.3, −109.4, −121.5, −122.0

### Elemental Analysis:

Calculated value C, 44.10%; H, 1.65%

Measured value C, 43.98%; H, 1.72%

### Synthesis Example 2

Synthesis of 1,4-Bis(4-fluorophenyl)perfluorobutane (FPPFB) In a round-bottomed flask (100 mL) equipped with a stirring bar, a Dimroth condenser, and a nitrogen introducing tube, 1-fluoro-4-iodobenzene (1.25 mL, 10.8 mmol), dimethyl sulfoxide (DMSO, 15 mL), and 1,4-diiodoperfluorobutane (2.46 g, 5.42 mmol) were placed and dissolved. Thereafter, a copper powder (1.56 g, 24.4 mmol) was added thereto, the temperature of the resultant mixture was increased in stages to 120° C. in a nitrogen gas atmosphere, and the mixture was then stirred for 48 hours. After the mixture was left standing to cool to room temperature, the copper powder was removed by suction filtration, and DMSO was distilled away by reduced-pressure distillation. The residue was dissolved in diethyl ether, the resultant solution was subjected to suction filtration, and the filtrate was then washed with distilled water. An organic layer was taken out, and anhydrous sodium sulfate was added thereto to perform dehydration. Thereafter, the resultant was filtered to obtain a filtrate, and diethyl ether was distilled away from the filtrate to give a crude product. The crude yield was 0.95 g, 45%. Purification was performed by reduced-pressure distillation (100° C./0.17 Torr) to give a white crystalline product (yield 0.93 g, 44%).

Melting point: 63 to 64° C.

¹H-NMR (DMSO-d₆, ppm): 7.69 (4H), 7.43 (4H)

¹³C-NMR (DMSO-d₆, ppm): 165.4, 163.4, 129.5, 124.4, 116.5, 116.3

¹⁹F-NMR (DMSO-d₆, ppm): −107.7, −109.3, −121.4

### Elemental Analysis:

Calculated value C, 49.24%; H, 2.07%
Measured value C, 48.89%; H, 1.93%

### Synthesis Example 3

Synthesis of 1,6-Bis(4-chlorophenyl)perfluorohexane (CPPFH) In a round-bottomed flask (100 mL) equipped with a stirring bar, a Dimroth condenser, and a nitrogen introducing tube, 1-chloro-4-iodobenzene (4.77 g, 20 mmol), dimethyl sulfoxide (DMSO, 15 mL), and 1,6-diiodoperfluorohexane (5.54 g, 10 mmol) were placed and dissolved. Thereafter, a copper powder (3.18 g, 50 mmol) was added thereto, the temperature of the resultant mixture was increased in stages to 120° C. in a nitrogen gas atmosphere, and the mixture was then stirred for 12 hours. After the mixture was left standing to cool to room temperature, the copper powder was removed by suction filtration, and DMSO was distilled away by reduced-pressure distillation. The residue was dissolved in t-butyl methyl ether, the resultant solution was subjected to suction filtration, and the filtrate was then washed with distilled water. An organic layer was taken out, and anhydrous sodium sulfate was added thereto to perform dehydration. Thereafter, the resultant was filtered to obtain a filtrate, and t-butyl methyl ether was distilled away from the filtrate to give a crude product. The crude product was purified by sublimation (80° C./0.2 Torr) to give a white powdery crystalline product (yield 4.55 g, 87%).

Melting point: 87 to 88° C.

¹H-NMR (CDCl₃, ppm): 7.53 (4H), 7.47 (4H)

¹³C-NMR (CDCl₃, ppm): 138.6, 129.1, 128.5, 128.4

¹⁹F-NMR (CDCl₃, ppm): −111.8, −122.4, −123.0

FT-IR (KBr, cm⁻¹): 1604 (C═C), 1216-1132 (C—F), 1092 (C—Cl)

Elemental Analysis (C₁₈H₈F₁₂Cl₂):

Calculated value C, 41.32%; H, 1.54%

Measured value C, 41.41%; H, 1.68%

### Synthesis Example 4

### Synthesis of 1,6-Bis(4-Nitrophenyl)Perfluorohexane (NPPFH)

In a round-bottomed flask (100 mL) equipped with a stirring bar, a Dimroth condenser, and a nitrogen introducing tube, 1-iodo-4-nitrobenzene (4.98 g, 20 mmol), dimethyl sulfoxide (DMSO, 15 mL), and 1,6-diiodoperfluorohexane (5.54 g, 10 mmol) were placed and dissolved. Thereafter, a copper powder (3.18 g, 50 mmol) was added thereto, the temperature of the resultant mixture was increased in stages to 120° C. in a nitrogen gas atmosphere, and the mixture was then stirred for 12 hours. After the mixture was left standing to cool to room temperature, the copper powder was removed by suction filtration, and DMSO was distilled away by reduced-pressure distillation. The residue was dissolved in t-butyl methyl ether, the resultant solution was subjected to suction filtration, and the filtrate was then washed with distilled water. An organic layer was taken out, and anhydrous sodium sulfate was added thereto to perform dehydration. Thereafter, the resultant was filtered to obtain a filtrate, and t-butyl methyl ether was distilled away from the filtrate to give a crude product. After the crude product was purified by sublimation (160° C./0.17 Torr), recrystallization was performed with a mixed solvent of THF/hexane. The recrystallized product was dried under reduced pressure at 100° C. for 12 hours to give a light-yellow needle crystalline product (yield 2.78 g, 51%).

Melting point: 168 to 169° C.

¹H-NMR (CDCl₃, ppm): 8.39 (4H), 7.82 (4H)

¹³C-NMR (CDCl₃, ppm): 150.3, 135.1, 128.6, 124.0

¹⁹F-NMR (CDCl₃, ppm): −112.0, −122.0, −122.4

FT-IR (KBr, cm⁻¹): 1550 (NO₂), 1291 (NO₂), 1215-1132 (C—F)

Elemental Analysis (C₁₈H₈N₂O₄F₁₂):

Calculated value C, 39.72%; H, 1.48%; N, 5.15%

Measured value C, 39.46%; H, 1.55%; N, 5.12%

### Example 1

Synthesis of Fluorine-Containing Polyether (FPPFH-BisZ)

In a two-necked flask (50 mL) equipped with a stirring bar, a nitrogen introducing tube, a Dean-Stark trap, and a Dimroth condenser, FPPFH (0.981 g, 2.0 mmol) and 4,4′-(cyclohexylidene)bisphenol (BisZ, 0.537 g, 2.0 mmol) were placed and dissolved in distilled 1,3-dimethyl-2-imidazolidone (DMI, 5.0 mL). Thereafter, potassium carbonate (0.332 g, 2.4 mmol) and toluene (20 mL) were added thereto. The temperature of the resultant mixture was increased in stages to 150° C., and the mixture was then stirred at 150° C. for 2 hours to remove water by azeotropy. Thereafter, the mixture was stirred at 170° C. for 12 hours. After the mixture was left standing to cool to room temperature, a polymer was collected with methanol. The polymer was cleaned with methanol while heating, and then dried under reduced pressure at room temperature. The polymer was dissolved in chloroform, and the resultant solution was poured into a large amount of methanol to purify the polymer by reprecipitation. The polymer was dried under reduced pressure at room temperature for 10 hours.

Yield of polymer: 1.09 g (72%)

Logarithmic viscosity (ηᵢₙₕ): 1.26 dL/g (0.5 g/dL concentration solution in NMP, measured at 30° C.)

Number average molecular weight (Mn): 200,000, Molecular weight distribution (Mw/Mn): 2.4

This polymer was dissolved in chloroform, and the resultant solution was cast onto a glass plate and dried at room temperature for 6 hours, subsequently at 50° C. for 3 hours, and then under reduced pressure at 100° C. for 3 hours to prepare a colorless transparent cast film (film thickness 35 μm).

FT-IR (film, cm⁻¹): 2937 (C—H), 2862 (C—H), 1600 (C═C), 1504 (C═C), 1292-1143 (C—F)

Solubility: soluble to NMP, DMAc, TMU, DMI, THF, chloroform, ethyl acetate, cyclohexanone, and cyclopentanone at room temperature

5% Weight loss temperature: 387° C. (in air), 492° C. (in nitrogen)

10% Weight loss temperature: 404° C. (in air), 504° C. (in nitrogen)

Carbonization yield: 42% (in nitrogen, 800° C.)

Glass transition temperature (Tg): 112° C. (DSC), 113° C. (TMA), 109° C. (DMA)

Coefficient of thermal expansion (CTE): 88 ppm/° C. (50° C. to 80° C.)

Tensile strength at break: 45 MPa

Elongation at break: 5.2%

Tensile elasticity: 1.4 GPa

Cut-off wavelength: 290 nm

Transmission at 500 nm: 83%,

Average refractive index (nₐᵥₑ): 1.538 (d line)

Birefringence (Δn): 0.001 (d line)

Dielectric constant (ε) calculated from refractive index: 2.37 (ε=nₐᵥₑ²)

Dielectric constant (Dk): 2.44 (TE mode, 10 GHz), 2.38 (TE mode, 20 GHz)

Dielectric dissipation factor (Df): 0.0021 (TE mode, 10 GHz), 0.0022 (TE mode, 20 GHz)

### Example 2

Synthesis of Fluorine-Containing Polyether (FPPFH-BisP3MZ)

In a two-necked flask (50 mL) equipped with a stirring bar, a nitrogen introducing tube, a Dean-Stark trap, and a Dimroth condenser, FPPFH (0.981 g, 2.0 mmol) and 4,4′-(3-methylcyclohexylidene)bisphenol (BisP3MZ, 0.565 g, 2.0 mmol) were placed and dissolved in distilled 1,3-dimethyl-2-imidazolidone (DMI, 5.0 mL). Thereafter, potassium carbonate (0.332 g, 2.4 mmol) and toluene (20 mL) were added thereto. The temperature of the resultant mixture was increased in stages to 150° C., and the mixture was then stirred at 150° C. for 2 hours to remove water by azeotropy. Thereafter, the mixture was stirred at 170° C. for 24 hours. After the mixture was left standing to cool to room temperature, a polymer was collected with methanol. The polymer was cleaned with methanol while heating, and then dried under reduced pressure at room temperature. The polymer was dissolved in chloroform, and the resultant solution was poured into a large amount of methanol to purify the polymer by reprecipitation. The polymer was dried under reduced pressure at room temperature for 10 hours.

Yield of polymer: 1.19 g (77%)

Logarithmic viscosity (ηᵢₙₕ): 0.76 dL/g (0.5 g/dL concentration solution in NMP, measured at 30° C.)

Number average molecular weight (Mn): 98,000, Molecular weight distribution (Mw/Mn): 2.7

This polymer was dissolved in chloroform, and the resultant solution was cast onto a glass plate and dried at room temperature for 6 hours, subsequently at 50° C. for 3 hours, and then under reduced pressure at 120° C. for 3 hours to prepare a colorless transparent cast film (film thickness 50 μm).

FT-IR (film, cm⁻¹): 2937 (C—H), 2862 (C—H), 1600 (C═C), 1504 (C═C), 1292-1143 (C—F)

¹H-NMR (CDCl₃, ppm): 7.51 (d, 4H), 7.37 (d, 2H), 7.18 (d, 2H), 7.02 (q, 6H), 6.91 (d, 2H), 2.62 (q, 2H), 1.82 (t, 1H), 1.71 (d, 2H), 1.52 (q, 3H), 0.96 (d, 4H)

¹³C-NMR (CDCl₃, ppm): 160.9, 153.4, 148.0, 141.9, 129.7, 128.8, 127.9, 123.1, 119.9, 117.8, 46.3, 37.0, 35.2, 28.8, 23.1

¹⁹F-NMR (CDCl₃, ppm): −111.1, −122.6, −123.2

Solubility: soluble to NMP, DMAc, TMU, DMI, THF, chloroform, ethyl acetate, cyclohexanone, and cyclopentanone at room temperature

5% Weight loss temperature: 379° C. (in air), 479° C. (in nitrogen)

10% Weight loss temperature: 393° C. (in air), 490° C. (in nitrogen)

Carbonization yield: 46% (in nitrogen, 800° C.)

Glass transition temperature (Tg): 132° C. (DSC), 132° C. (TMA), 128° C. (DMA)

Coefficient of thermal expansion (CTE): 88 ppm/° C. (50° C. to 80° C.)

Tensile strength at break: 53 MPa

Elongation at break: 4.3%

Tensile elasticity: 1.4 GPa

Cut-off wavelength: 292 nm

Transmission at 500 nm: 80%,

Average refractive index (ηᵢₙₕ): 1.531 (d line)

Birefringence (Δn): 0.004 (d line)

Dielectric constant (ε) calculated from refractive index: 2.34 (ϵ=nₐᵥₑ²)

Dielectric constant (Dk): 2.43 (TE mode, 10 GHz), 2.37 (TE mode, 20 GHz)

Dielectric dissipation factor (Df): 0.0015 (TE mode, 10 GHz), 0.0016 (TE mode, 20 GHz)

### Example 3

Synthesis of Fluorine-Containing Polyether (FPPFH-BisPHTG) In a two-necked flask (50 mL) equipped with a stirring bar, a nitrogen introducing tube, a Dean-Stark trap, and a Dimroth condenser, FPPFH (0.981 g, 2.0 mmol) and 4,4′-(3,3,5-trimethylcyclohexylidene)bisphenol (BisPHTG, 0.621 g, 2.0 mmol) were placed and dissolved in distilled 1,3-dimethyl-2-imidazolidone (DMI, 5.0 mL). Thereafter, potassium carbonate (0.332 g, 2.4 mmol) and toluene (20 mL) were added thereto. The temperature of the resultant mixture was increased in stages to 150° C., and the mixture was then stirred at 150° C. for 2 hours to remove water by azeotropy. Thereafter, the mixture was stirred at 170° C. for 24 hours. After the mixture was left standing to cool to room temperature, a polymer was collected with methanol. The polymer was cleaned with methanol while heating, and then dried under reduced pressure at room temperature. The polymer was dissolved in chloroform, and the resultant solution was poured into a large amount of methanol to purify the polymer by reprecipitation. The polymer was dried under reduced pressure at room temperature for 10 hours.

Yield of polymer: 1.33 g (83%)

Logarithmic viscosity (ηᵢₙₕ): 0.45 dL/g (0.5 g/dL concentration solution in NMP, measured at 30° C.)

Number average molecular weight (Mn): 43,000, Molecular weight distribution (Mw/Mn): 2.2

This polymer was dissolved in chloroform, and the resultant solution was cast onto a glass plate and dried at room temperature for 6 hours, subsequently at 50° C. for 3 hours, and then under reduced pressure at 120° C. for 3 hours to prepare a colorless transparent cast film (film thickness 51 μm).

FT-IR (film, cm⁻¹): 2937 (C—H), 2862 (C—H), 1600 (C═C), 1504 (C═C), 1292-1143 (C—F)

¹H-NMR (CDCl₃, ppm): 7.49 (t, 4H), 7.38 (d, 2H), 7.25 (t, 2H), 6.99 (q, 6H), 6.92 (d, 2H), 2.72 (d, 1H), 2.49 (d, 1H), 2.04 (s, 1H), 1.96 (d, 1H), 1.44 (d, 1H), 1.21 (t, 1H), 1.01 (d, 6H), 0.90 (t, 1H), 0.41 (s, 3H)

¹³C-NMR (CDCl₃, ppm): 160.9, 153.1, 148.8, 143.3, 129.3, 128.8, 127.6, 123.1, 119.8, 117.6, 48.8, 48.4, 46.3, 45.4, 35.0, 32.4, 26.9, 25.7, 22.8

¹⁹F-NMR (CDCl₃, ppm): −111.1, −122.6, −123.2 Solubility: soluble to NMP, DMAc, TMU, DMI, THF, chloroform, ethyl acetate, cyclohexanone, cyclopentanone, and acetone at room temperature

5% Weight loss temperature: 458° C. (in air), 493° C. (in nitrogen)

10% Weight loss temperature: 482° C. (in air), 503° C. (in nitrogen)

Carbonization yield: 38% (in nitrogen, 800° C.)

Glass transition temperature (Tg): 140° C. (DSC), 136° C. (TMA), 130° C. (DMA)

Coefficient of thermal expansion (CTE): 96 ppm/° C. (50° C. to 80° C.)

Tensile strength at break: 53 MPa

Elongation at break: 4.8%

Tensile elasticity: 1.5 GPa

Cut-off wavelength: 293 nm

Transmission at 500 nm: 85%,

Average refractive index (nₐᵥₑ): 1.523 (d line)

Birefringence (Δn): 0.002 (d line)

Dielectric constant (ε) calculated from refractive index: 2.32 (ε=nₐᵥₑ²)

Dielectric constant (Dk): 2.42 (TE mode, 10 GHz), 2.36 (TE mode, 20 GHz)

Dielectric dissipation factor (Df): 0.0033 (TE mode, 10 GHz), 0.0036 (TE mode, 20 GHz)

### Example 4

Synthesis of Fluorine-Containing Polyether (FPPFH-BisPCDE)

In a two-necked flask (50 mL) equipped with a stirring bar, a nitrogen introducing tube, a Dean-Stark trap, and a Dimroth condenser, FPPFH (0.981 g, 2.0 mmol) and 4,4′-cyclododecylidenebisphenol (BisPCDE, 0.705 g, 2.0 mmol) were placed and dissolved in distilled 1,3-dimethyl-2-imidazolidone (DMI, 5.0 mL). Thereafter, potassium carbonate (0.332 g, 2.4 mmol) and toluene (20 mL) were added thereto. The temperature of the resultant mixture was increased in stages to 150° C., and the mixture was then stirred at 150° C. for 2 hours to remove water by azeotropy. Thereafter, the mixture was stirred at 170° C. for 24 hours. After the mixture was left standing to cool to room temperature, a polymer was collected with methanol. The polymer was cleaned with methanol while heating, and then dried under reduced pressure at room temperature. The polymer was dissolved in chloroform, and the resultant solution was poured into a large amount of methanol to purify the polymer by reprecipitation. The polymer was dried under reduced pressure at room temperature for 10 hours.

Yield of polymer: 1.28 g (76%)

Logarithmic viscosity (ηᵢₙₕ): 0.64 dL/g (0.5 g/dL concentration solution in NMP, measured at 30° C.)

Number average molecular weight (Mn): 68,000, Molecular weight distribution (Mw/Mn): 2.3

This polymer was dissolved in chloroform, and the resultant solution was cast on a glass plate and dried at room temperature for 6 hours, subsequently at 50° C. for 3 hours, and then under reduced pressure at 140° C. for 5 hours to prepare a colorless transparent cast film (film thickness 56 μm).

FT-IR (film, cm⁻¹): 2937 (C—H), 2862 (C—H), 1600 (C═C), 1504 (C═C), 1292-1143 (C—F)

Solubility: soluble to NMP, DMAc, TMU, DMI, THF, chloroform, ethyl acetate, cyclohexanone, and cyclopentanone at room temperature

5% Weight loss temperature: 343° C. (in air), 423° C. (in nitrogen)

10% Weight loss temperature: 364° C. (in air), 441° C. (in nitrogen)

Carbonization yield: 36% (in nitrogen, 800° C.)

Glass transition temperature (Tg): 155° C. (DSC), 156° C. (TMA), 151° C. (IDMA)

Coefficient of thermal expansion (CTE): 85 ppm/° C. (50° C. to 80° C.)

Tensile strength at break: 64 MPa

Elongation at break: 6.1%

Tensile elasticity: 1.7 GPa

Cut-off wavelength: 292 nm

Transmission at 500 nm: 78%,

Average refractive index (nₐᵥₑ): 1.527 (d line)

Birefringence (Δn): 0.002 (d line)

Dielectric constant (ε) calculated from refractive index: 2.33 (ε=nₐᵥₑ²)

Dielectric constant (Dk): 2.42 (TE mode, 10 GHz), 2.37 (TE mode, 20 GHz)

Dielectric dissipation factor (Df): 0.0011 (TE mode, 10 GHz), 0.0012 (TE mode, 20 GHz)

### Example 5

Synthesis of Fluorine-Containing Polyether (FPPFH-BisPIND)

In a two-necked flask (50 mL) equipped with a stirring bar, a nitrogen introducing tube, a Dean-Stark trap, and a Dimroth condenser, FPPFH (0.981 g, 2.0 mmol) and 3-(4-hydroxyphenyl)-1,1,3-trimethyl-5-indanol (BisPIND, 0.537 g, 2.0 mmol) were placed and dissolved in distilled 1,3-dimethyl-2-imidazolidone (DMI, 5.0 mL). Thereafter, potassium carbonate (0.332 g, 2.4 mmol) and toluene (20 mL) were added thereto. The temperature of the resultant mixture was increased in stages to 150° C., and the mixture was then stirred at 150° C. for 2 hours to remove water by azeotropy. Thereafter, the mixture was stirred at 170° C. for 24 hours. After the mixture was left standing to cool to room temperature, a polymer was collected with methanol. The polymer was cleaned with methanol while heating, and then dried under reduced pressure at room temperature. The polymer was dissolved in chloroform, and the resultant solution was poured into a large amount of methanol to purify the polymer by reprecipitation. The polymer was dried under reduced pressure at room temperature for 10 hours.

Yield of polymer: 0.97 g (64%)

Logarithmic viscosity (ηᵢₙₕ): 0.91 dL/g (0.5 g/dL concentration solution in NMP, measured at 30° C.)

Number average molecular weight (Mn): 116,000, Molecular weight distribution (Mw/Mn): 2.7

This polymer was dissolved in chloroform, and the resultant solution was cast onto a glass plate and dried at room temperature for 6 hours, subsequently at 50° C. for 3 hours, and then under reduced pressure at 110° C. for 3 hours to prepare a colorless transparent cast film (film thickness 58 μm).

FT-IR (film, cm⁻¹): 2937 (C—H), 2862 (C—H), 1600 (C═C), 1504 (C═C), 1292-1143 (C—F)

¹H-NMR (CDCl₃, ppm): 7.49 (d, 4H), 7.19 (t, 3H), 7.04-6.92 (q, 7H), 6.84 (d, 1H), 2.45 (d, 1H), 2.27 (d, 1H), 1.68 (s, 3H), 1.37 (s, 3H), 1.09 (s, 3H)

¹³C-NMR (CDCl₃, ppm): 161.4, 161.0, 154.5, 153.4, 151.1, 148.7, 146.9, 128.8, 128.3, 124.2, 119.7, 117.6, 116.8, 59.6, 50.5, 42.7, 30.9

¹⁹F-NMR (CDCl₃, ppm): −111.1, −122.6, −123.1

Solubility: soluble to DMF, DMAc, NMP, TMU, DMI, THF, chloroform, ethyl acetate, cyclohexanone, cyclopentanone, and acetone at room temperature

5% Weight loss temperature: 425° C. (in air), 493° C. (in nitrogen)

10% Weight loss temperature: 440° C. (in air), 501° C. (in nitrogen)

Carbonization yield: 51% (in nitrogen, 800° C.)

Glass transition temperature (Tg): 123° C. (DSC), 125° C. (TMA), 121° C. (DMA)

Coefficient of thermal expansion (CTE): 90 ppm/° C. (50° C. to 80° C.)

Tensile strength at break: 43 MPa

Elongation at break: 3.6%

Tensile elasticity: 1.1 GPa

Cut-off wavelength: 293 nm

Transmission at 500 nm: 84%,

Average refractive index (nₐᵥₑ): 1.527 (d line) Birefringence (Δn): 0.001 (d line)

Dielectric constant (ε) calculated from refractive index: 2.33 (ε=nₐᵥₑ²)

Dielectric constant (Dk): 2.43 (TE mode, 10 GHz), 2.36 (TE mode, 20 GHz)

Dielectric dissipation factor (Df): 0.0031 (TE mode, 10 GHz), 0.0033 (TE mode, 20 GHz)

### Example 6

Synthesis of Fluorine-Containing Polyether (FPPFH-BPFL)

In a two-necked flask (50 mL) equipped with a stirring bar, a nitrogen introducing tube, a Dean-Stark trap, and a Dimroth condenser, FPPFH (0.981 g, 2.0 mmol) and 9,9-bis(4-hydroxyphenyl)fluorene (BPFL, 0.701 g, 2.0 mmol) were placed and dissolved in distilled 1,3-dimethyl-2-imidazolidone (DMI, 5.0 mL). Thereafter, potassium carbonate (0.332 g, 2.4 mmol) and toluene (20 mL) were added thereto. The temperature of the resultant mixture was increased in stages to 150° C., and the mixture was then stirred at 150° C. for 2 hours to remove water by azeotropy. Thereafter, the mixture was stirred at 170° C. for 24 hours. After the mixture was left standing to cool to room temperature, a polymer was collected with methanol. The polymer was cleaned with methanol while heating, and then dried under reduced pressure at room temperature. The polymer was dissolved in chloroform, and the resultant solution was poured into a large amount of methanol to purify the polymer by reprecipitation. The polymer was dried under reduced pressure at room temperature for 10 hours.

Yield of polymer: 1.28 g (76%)

Logarithmic viscosity (ηᵢₙₕ): 1.15 dL/g (0.5 g/dL concentration solution in NMP, measured at 30° C.)

Number average molecular weight (Mn): 144,000, Molecular weight distribution (Mw/Mn): 2.3

This polymer was dissolved in chloroform, and the resultant solution was cast onto a glass plate and dried at room temperature for 6 hours, subsequently at 50° C. for 3 hours, and then under reduced pressure at 160° C. for 3 hours to prepare a colorless transparent cast film (film thickness 53 μm).

FT-IR (film, cm⁻¹): 2937 (C—H), 2862 (C—H), 1600 (C═C), 1504 (C═C), 1292-1143 (C—F)

¹H-NMR (CDCl₃, ppm): 7.78 (d, 2H), 7.49 (d, 4H), 7.41 (d, 4H), 7.32 (t, 2H), 7.23 (d, 4H), 7.02 (d, 4H), 6.90 (d, 4H)

¹³C-NMR (CDCl₃, ppm): 160.6, 154.6, 151.1, 142.0, 140.2, 129.8, 128.8, 127.9, 126.2, 123.4, 120.5, 119.7, 117.9, 64.6

¹⁹F-NMR (CDCl₃, ppm): −111.2, −122.7, −123.2

### Elemental Analysis:

Calculated value C, 64.50%; H, 3.02%
Measured value C, 64.17%; H, 3.14%

Solubility: soluble to DMF, DMAc, NMP, TMU, DMI, THF, chloroform, ethyl acetate, cyclohexanone, and cyclopentanone at room temperature

5% Weight loss temperature: 530° C. (in air), 546° C. (in nitrogen)

10% Weight loss temperature: 550° C. (in air), 562° C. (in nitrogen)

Carbonization yield: 57% (in nitrogen, 800° C.)

Glass transition temperature (Tg): 172° C. (DSC), 172° C. (TMA) 171° C. (DMA)

Coefficient of thermal expansion (CTE): 71 ppm/° C. (50° C. to 80° C.)

Tensile strength at break: 54 MPa

Elongation at break: 4.8%

Tensile elasticity: 1.6 GPa

Cut-off wavelength: 316 nm

Transmission at 500 nm: 80%,

Average refractive index (nₐᵥₑ): 1.572 (d line) Birefringence (Δn): 0.002 (d line)

Dielectric constant (ε) calculated from refractive index: 2.47 (ε=nₐᵥₑ²)

Dielectric constant (Dk): 2.46 (TE mode, 10 GHz), 2.41 (TE mode, 20 GHz)

Dielectric dissipation factor (Df): 0.0019 (TE mode, 10 GHz), 0.0020 (TE mode, 20 GHz)

### Example 7

Synthesis of Fluorine-Containing Polyether (FPPFH-BMPFL)

In a two-necked flask (50 mL) equipped with a stirring bar, a nitrogen introducing tube, a Dean-Stark trap, and a Dimroth condenser, FPPFH (0.981 g, 2.0 mmol) and 9,9-bis(4-hydroxy-3-methylphenyl)fluorene (BMPFL, 0.757 g, 2.0 mmol) were placed and dissolved in distilled 1,3-dimethyl-2-imidazolidone (DMI, 5.0 mL). Thereafter, potassium carbonate (0.332 g, 2.4 mmol) and toluene (20 mL) were added thereto. The temperature of the resultant mixture was increased in stages to 150° C., and the mixture was then stirred at 150° C. for 2 hours to remove water by azeotropy. Thereafter, the mixture was stirred at 170° C. for 24 hours. After the mixture was left standing to cool to room temperature, a polymer was collected with methanol. The polymer was cleaned with methanol while heating, and then dried under reduced pressure at room temperature. The polymer was dissolved in chloroform, and the resultant solution was poured into a large amount of methanol to purify the polymer by reprecipitation. The polymer was dried under reduced pressure at room temperature for 10 hours.

Yield of polymer: 1.41 g (81%)

Logarithmic viscosity (ηᵢₙₕ): 0.42 dL/g (0.5 g/dL concentration solution in NMP, measured at 30° C.)

Number average molecular weight (Mn): 45,000, Molecular weight distribution (Mw/Mn): 2.4

This polymer was dissolved in chloroform, and the resultant solution was cast onto a glass plate and dried at room temperature for 6 hours, subsequently at 50° C. for 3 hours, and then under reduced pressure at 160° C. for 3 hours to prepare a colorless transparent cast film (film thickness 53 μm).

¹H-NMR (CDCl₃, ppm): 7.81 (d, 2H), 7.47 (m, 6H), 7.40 (t, 2H), 7.32 (t, 2H), 7.11 (d, 4H), 6.94 (d, 4H), 6.85 (d, 2H), 2.08 (s, 6H)

¹⁹F-NMR (CDCl₃, ppm): −110.9, −122.5, −123.0

Solubility: soluble to DMF, DMAc, NMP, TMU, DMI, THF, chloroform, ethyl acetate, cyclohexanone, and cyclopentanone at room temperature

5% Weight loss temperature: 426° C. (in air), 439° C. (in nitrogen)

10% Weight loss temperature: 452° C. (in air), 461° C. (in nitrogen)

Carbonization yield: 64% (in nitrogen, 800° C.)

Glass transition temperature (Tg): 168° C. (DSC), 169° C. (TMA), 166° C. (DMA)

Coefficient of thermal expansion (CTE): 81 ppm/° C. (50° C. to 80° C.)

Tensile strength at break: 61 MPa

Elongation at break: 5.1%

Tensile elasticity: 2.1 GPa

Cut-off wavelength: 3116 nm

Transmission at 500 nm: 79%,

Average refractive index (nₐᵥₑ): 1.568 (d line)

Birefringence (Δn): 0.002 (d line)

Dielectric constant (ε) calculated from refractive index: 2.46 (ε=nₐᵥₑ²)

Dielectric constant (Dk): 2.45 (TE mode, 10 GHz), 2.40 (TE mode, 20 GHz)

Dielectric dissipation factor (Df): 0.0020 (TE mode, 10 GHz), 0.0019 (TE mode, 20 GHz)

### Example 8

Synthesis of Fluorine-Containing Polyether (FPPFH-BP)

In a two-necked flask (50 mL) equipped with a stirring bar, a nitrogen introducing tube, a Dean-Stark trap, and a Dimroth condenser, FPPFH (0.981 g, 2.0 mmol) and 4,4-dihydroxybiphenyl (BP, 0.372 g, 2.0 mmol) were placed and dissolved in distilled 1,3-dimethyl-2-imidazolidone (DMI, 5.0 mL). Thereafter, potassium carbonate (0.332 g, 2.4 mmol) and toluene (20 mL) were added thereto. The temperature of the resultant mixture was increased in stages to 150° C., and the mixture was then stirred at 150° C. for 2 hours to remove water by azeotropy. Thereafter, the mixture was stirred at 170° C. for 12 hours. After the mixture was left standing to cool to room temperature, a polymer was collected with methanol. The polymer was cleaned with methanol while heating, and then dried under reduced pressure at room temperature. The polymer was dissolved in tetrahydrofuran (THF), and the resultant solution was poured into a large amount of methanol to purify the polymer by reprecipitation. The polymer was dried under reduced pressure at room temperature for 10 hours.

Yield of polymer: 0.93 g (69%)

Logarithmic viscosity (ηᵢₙₕ): 0.85 dL/g (0.5 g/dL concentration solution in NMP, measured at 30° C.)

This polymer was dissolved in THF, and the resultant solution was cast onto a glass plate and dried at room temperature for 6 hours, subsequently at 50° C. for 3 hours, and then under reduced pressure at 90° C. for 3 hours to prepare a colorless transparent cast film (film thickness 42 μm).

FT-IR (film, cm⁻¹): 1600 (C═C), 1504 (C═C), 1292-1143 (C—F)

Solubility: soluble to DMAc, NMP, TMU, DMI, THF, and cyclopentanone at room temperature

5% Weight loss temperature: 507° C. (in air), 542° C. (in nitrogen)

10% Weight loss temperature: 531° C. (in air), 555° C. (in nitrogen)

Carbonization yield: 44% (in nitrogen, 800° C.)

Glass transition temperature (Tg): 103° C. (DSC), 105° C. (TMA) 114° C. (DMA)

Coefficient of thermal expansion (CTE): 94 ppm/° C. (50° C. to 80° C.)

Tensile strength at break: 27 MPa

Elongation at break: 16.7%

Tensile elasticity: 1.1 GPa

Cut-off wavelength: 308 nm

Transmission at 500 nm: 86%,

Average refractive index (nₐᵥₑ): 1.551 (d line)

Birefringence (Δn): 0.011 (d line)

Dielectric constant (ε) calculated from refractive index: 2.41 (ε=nₐᵥₑ²)

Dielectric constant (Dk): 2.44 (TE mode, 10 GHz), 2.40 (TE mode, 20 GHz)

Dielectric dissipation factor (Df): 0.0021 (TE mode, 10 GHz), 0.0023 (TE mode, 20 GHz)

### Example 9

Synthesis of Fluorine-Containing Polyether (FPPFH-NDO)

In a two-necked flask (50 mL) equipped with a stirring bar, a nitrogen introducing tube, a Dean-Stark trap, and a Dimroth condenser, FPPFH (0.981 g, 2.0 mmol) and 2,6-dihydroxynaphthalene (NDO, 0.320 g, 2.0 mmol) were placed and dissolved in distilled 1,3-dimethyl-2-imidazolidone (DMI, 5.0 mL). Thereafter, potassium carbonate (0.332 g, 2.4 mmol) and toluene (20 mL) were added thereto. The temperature of the resultant mixture was increased in stages to 150° C., and the mixture was then stirred at 150° C. for 2 hours to remove water by azeotropy. Thereafter, the mixture was stirred at 170° C. for 24 hours. After the mixture was left standing to cool to room temperature, a polymer was collected with methanol. The polymer was cleaned with methanol while heating, and then dried under reduced pressure at room temperature. The polymer was dissolved in tetrahydrofuran (THF), and the resultant solution was poured into a large amount of methanol to purify the polymer by reprecipitation. The polymer was dried under reduced pressure at room temperature for 10 hours.

Logarithmic viscosity (ηᵢₙₕ): 0.41 dL/g (0.5 g/dL concentration solution in NMP, measured at 30° C.)

This polymer was dissolved in THF, and the resultant solution was cast onto a glass plate and dried at room temperature for 6 hours, subsequently at 50° C. for 3 hours, and then under reduced pressure at 90° C. for 3 hours to prepare a light-yellow transparent cast film.

Solubility: soluble to DMF, DMAc, NMP, TMU, DMI, THF, and cyclopentanone at room temperature

5% Weight loss temperature: 438° C. (in air), 535° C. (in nitrogen)

10% Weight loss temperature: 484° C. (in air), 556° C. (in nitrogen)

Carbonization yield: 49% (in nitrogen, 800° C.)

Glass transition temperature (Tg): 97° C. (DSC), 98° C. (TMA), 98° C. (DMA)

Coefficient of thermal expansion (CTE): 99 ppm/° C. (50° C. to 80° C.)

Tensile strength at break: 28 MPa

Elongation at break: 3.9%

Tensile elasticity: 1.3 GPa

Cut-off wavelength: 348 nm

Transmission at 500 nm: 55%,

Average refractive index (nₐᵥₑ): 1.554 (d line)

Birefringence (Δn): 0.002 (d line)

Dielectric constant (ε) calculated from refractive index: 2.41 (ε=nₐᵥₑ²)

Dielectric constant (Dk): 2.45 (TE mode, 10 GHz), 2.42 (TE mode, 20 GHz)

Dielectric dissipation factor (Df): 0.0032 (TE mode, 10 GHz), 0.0032 (TE mode, 20 GHz)

### Example 10

Synthesis of Fluorine-Containing Polyether (FPPFH-TMPBP)

A polyether was synthesized by performing polymerization at 190° C. for 24 hours using 4,4′-dihydroxy-2,2′,3,3′,5,5′-hexamethylbiphenyl (TMPBP) in place of 4,4-dihydroxybiphenyl (BP) in Example 8.

Yield of polymer: 76%

Logarithmic viscosity (ηᵢₙₕ): 0.47 dL/g (0.5 g/dL concentration solution in NMP, measured at 30° C.)

Number average molecular weight (Mn): 50,000, Molecular weight distribution (Mw/Mn): 2.4

This polymer was dissolved in THF to prepare a transparent cast film (film thickness 60 μm).

FT-IR (film, cm⁻¹): 1600 (C═C), 1504 (C═C), 1292-1143 (C—F)

Elemental analysis (C₃₆H₂₈O₂F₁₂):
Calculated value C, 60.00%; H, 3.92%
Measured value C, 60.22%; H, 3.98%

Solubility: soluble to NMP, TMU, DMI, DMAc, THF, chloroform, ethyl acetate, cyclohexanone, and cyclopentanone

5% Weight loss temperature: 415° C. (in air), 432° C. (in nitrogen)

10% Weight loss temperature: 439° C. (in air), 446° C. (in nitrogen)

Carbonization yield: 52% (in nitrogen, 800° C.)

Glass transition temperature (Tg): 167° C. (DSC), 169° C. (TMA), 166° C. (DMA)

Coefficient of thermal expansion (CTE): 82 ppm/° C. (50° C. to 80° C.)

Tensile strength at break: 48 MPa

Elongation at break: 4.3%

Tensile elasticity: 1.3 GPa

Cut-off wavelength: 308 nm

Transmission at 500 nm: 57%,

Average refractive index (nₐᵥₑ): 1.552 (d line)

Birefringence (Δn): 0.006 (d line)

Dielectric constant (ε) calculated from refractive index: 2.32 (ε=nₐᵥₑ²)

Dielectric constant (Dk): 2.39 (TE mode, 10 GHz), 2.33 (TE mode, 20 GHz)

Dielectric dissipation factor (Df): 0.0015 (TE mode, 10 GHz), 0.0016 (TE mode, 20 GHz)

### Example 11

Synthesis of Fluorine-Containing Polyether (FPPFH-BisTMP)

A polyether was synthesized by performing polymerization at 170° C. for 12 hours using 4,4-dihydroxytetraphenylmethane (BisTMP) in place of 4,4-dihydroxybiphenyl (BP) in Example 8.

Yield of polymer: 80%

Logarithmic viscosity (ηᵢₙₕ): 0.65 dL/g (0.5 g/dL concentration solution in NMP, measured at 30° C.)

Number average molecular weight (Mn): 61,000, Molecular weight distribution (Mw/Mn): 2.8 This polymer was dissolved in THF to prepare a colorless transparent cast film (film thickness 46 μm).

FT-IR (film, cm⁻¹): 1600 (C═C), 1504 (C═C), 1292-1143 (C—F)

### Elemental Analysis:

Calculated value C, 64.34%; H, 3.27%
Measured value C, 64.15%; H, 3.35%

Solubility: soluble to NMP, TMU, DMI, DMAc, and THF

5% Weight loss temperature: 498° C. (in air), 508° C. (in nitrogen)

10% Weight loss temperature: 514° C. (in air), 520° C. (in nitrogen)

Carbonization yield: 57% (in nitrogen, 800° C.)

Glass transition temperature (Tg): 133° C. (DSC), 143° C. (TMA), 135° C. (DMA)

Coefficient of thermal expansion (CTE): 70 ppm/° C. (50° C. to 80° C.)

Tensile strength at break: 46 MPa

Elongation at break: 3.2%

Tensile elasticity: 1.5 GPa

Cut-off wavelength: 292 nm

Transmission at 500 nm: 79%,

Average refractive index (nₐᵥₑ): 1.566 (d line)

Birefringence (Δn): 0.008 (d line)

Dielectric constant (ε) calculated from refractive index: 2.45 (ε=nₐᵥₑ²)

Dielectric constant (Dk): 2.45 (TE mode, 10 GHz), 2.44 (TE mode, 20 GHz)

Dielectric dissipation factor (Df): 0.0036 (TE mode, 10 GHz), 0.0038 (TE mode, 20 GHz)

### Example 12

Synthesis of Fluorine-Containing Polyether (FPPFH-TBISRX)

A polyether was synthesized by performing polymerization at 190° C. for 4 hours using spiro[fluorene-9,9′-xanthene]-3′,6′-diol (TBISRX) in place of 9,9-bis(4-hydroxyphenyl)fluorene (BPFL) in Example 6.

Yield of polymer: 81%

Logarithmic viscosity (ηᵢₙₕ): 0.81 dL/g (0.5 g/dL concentration solution in NMP, measured at 30° C.)

Number average molecular weight (Mn): 94,000, Molecular weight distribution (Mw/Mn): 2.9

This polymer was dissolved in chloroform to prepare a colorless transparent cast film (film thickness 50 μm).

FT-IR (film, cm⁻¹): 1600 (C═C), 1504 (C═C), 1292-1143 (C—F)

### Elemental Analysis:

Calculated value C, 63.40%; H, 2.72%
Measured value C, 63.69%; H, 2.89%

Solubility: soluble to NMP, TMU, DMI, DMAc, DMF, THF, chloroform, ethyl acetate, cyclohexanone, and cyclopentanone

5% Weight loss temperature: 507° C. (in air), 545° C. (in nitrogen)

10% Weight loss temperature: 525° C. (in air), 561° C. (in nitrogen)

Carbonization yield: 60% (in nitrogen, 800° C.)

Glass transition temperature (Tg): 190° C. (DSC), 205° C. (TMA), 189° C. (DMA)

Coefficient of thermal expansion (CTE): 65 ppm/° C. (50° C. to 80° C.)

Tensile strength at break: 58 MPa

Elongation at break: 5.8%

Tensile elasticity: 1.2 GPa

Cut-off wavelength: 315 nm

Transmission at 500 nm: 86%,

Average refractive index (nₐᵥₑ): 1.579 (d line)

Birefringence (Δn): 0.003 (d line)

Dielectric constant (ε) calculated from refractive index: 2.49 (ε=nₐᵥₑ²)

Dielectric constant (Dk): 2.46 (TE mode, 10 GHz), 2.44 (TE mode, 20 GHz)

Dielectric dissipation factor (Df): 0.0014 (TE mode, 10 GHz), 0.0015 (TE mode, 20 GHz)

### Example 13

Synthesis of Fluorine-Containing Polyether (FPPFB-BisA)

A polyether was synthesized by performing polymerization at 190° C. for 3 hours using 1,4-bis(4-fluorophenyl)perfluorobutane (FPPFB) in place of FPPFH in Comparative Example 1.

Yield of polymer: 80%

Logarithmic viscosity (ηᵢₙₕ): 1.06 dL/g (0.5 g/dL concentration solution in NMP, measured at 30° C.)

Number average molecular weight (Mn): 119,000, Molecular weight distribution (Mw/Mn): 2.5

This polymer was dissolved in chloroform to prepare a colorless transparent cast film (film thickness 48 μm).

FT-IR (film, cm⁻¹): 1600 (C═C), 1502 (C═C), 1287-1139 (C—F) Elemental analysis (C₃₁H₂₂O₂F₈):
Calculated value C, 64.36%; H, 3.83%
Measured value C, 64.72%; H, 3.87%

Solubility: soluble to NMP, TMU, DMI, DMAc, THF, chloroform, cyclohexanone, and cyclopentanone

5% Weight loss temperature: 445° C. (in air), 495° C. (in nitrogen)

10% Weight loss temperature: 458° C. (in air), 503° C. (in nitrogen)

Carbonization yield: 60% (in nitrogen, 800° C.)

Glass transition temperature (Tg): 113° C. (DSC), 112° C. (TMA), 111° C. (DMA)

Coefficient of thermal expansion (CTE): 105 ppm/° C. (50° C. to 80° C.)

Tensile strength at break: 35 MPa

Elongation at break: 3.7%

Tensile elasticity: 1.3 GPa

Cut-off wavelength: 289 nm

Transmission at 500 nm: 87%,

Average refractive index (nₐᵥₑ): 1.556 (d line)

Birefringence (Δn): 0.004 (d line)

Dielectric constant (ε) calculated from refractive index: 2.42 (ε=nₐᵥₑ²)

Dielectric constant (Dk): 2.44 (TE mode, 10 GHz), 2.40 (TE mode, 20 GHz)

Dielectric dissipation factor (Df): 0.0016 (TE mode, 10 GHz), 0.0017 (TE mode, 20 GHz)

### Example 14

Synthesis of Fluorine-Containing Polyether (FPPFB-BisAF)

A polyether was synthesized by performing polymerization at 190° C. for 3 hours using 1,4-bis(4-fluorophenyl)perfluorobutane (FPPFB) in place of FPPFH in Comparative Example 2.

Yield of polymer: 76%

Logarithmic viscosity (ηᵢₙₕ): 0.80 dL/g (0.5 g/dL concentration solution in NMP, measured at 30° C.)

Number average molecular weight (Mn): 86,000, Molecular weight distribution (Mw/Mn): 2.6 This polymer was dissolved in chloroform to prepare a colorless transparent cast film (film thickness 40 μm).

FT-IR (film, cm⁻¹): 1603 (C═C), 1507 (C═C), 1251-1138 (C—F), 1103 (C-0)

Elemental analysis (C₃₁H₁₆O₂F₁₄)
Calculated value C, 54.24%; H, 2.35%
Measured value C, 54.30%; H, 2.41%

Solubility: soluble to NMP, TMU, DMI, DMF, THF, chloroform, acetone, and ethyl acetate

5% Weight loss temperature: 483° C. (in air), 507° C. (in nitrogen)

10% Weight loss temperature: 500° C. (in air), 518° C. (in nitrogen)

Carbonization yield: 50% (in nitrogen, 800° C.)

Glass transition temperature (Tg): 122° C. (DSC), 122° C. (TMA), 119° C. (DMA)

Coefficient of thermal expansion (CTE): 84 ppm/° C. (50° C. to 80° C.)

Tensile strength at break: 36 MPa

Elongation at break: 3.0%

Tensile elasticity: 2.3 GPa

Cut-off wavelength: 281 nm

Transmission at 500 nm: 85%,

Average refractive index (nₐᵥₑ): 1.518 (d line)

Birefringence (Δn): 0.003 (d line)

Dielectric constant (ε) calculated from refractive index: 2.30 (ε=nₐᵥₑ²)

Dielectric constant (Dk): 2.21 (TE mode, 10 GHz), 2.18 (TE mode, 20 GHz)

Dielectric dissipation factor (Df): 0.0017 (TE mode, 10 GHz), 0.0019 (TE mode, 20 GHz)

### Example 15

Synthesis of Fluorine-Containing Polyether (FPPFB-BPFL)

A polyether was synthesized by performing polymerization at 190° C. for 6 hours using 1,4-bis(4-fluorophenyl)perfluorobutane (FPPFB) in place of FPPFH in Example 6.

Yield of polymer: 74%

Logarithmic viscosity (ηᵢₙₕ): 1.11 dL/g (0.5 g/dL concentration solution in NMP, measured at 30° C.)

Number average molecular weight (Mn): 130,000, Molecular weight distribution (Mw/Mn): 2.5

This polymer was dissolved in chloroform to prepare a colorless transparent cast film (film thickness 46 μm).

FT-IR (film, cm⁻¹): 1599 (C═C), 1500 (C═C), 1286-1139 (C—F) 1104 (C-0)

Elemental analysis (C₄₁H₂₄O₂F₈)
Calculated value C, 70.28%; H, 3.45%
Measured value C, 70.47%; H, 3.46%

Solubility: soluble to NMP, TMU, DMI, DMAc, DMF, THF, chloroform, ethyl acetate, cyclohexanone, and cyclopentanone

5% Weight loss temperature: 507° C. (in air), 533° C. (in nitrogen)

10% Weight loss temperature: 518° C. (in air), 547° C. (in nitrogen)

Carbonization yield: 69% (in nitrogen, 800° C.)

Glass transition temperature (Tg): 196° C. (DSC), 194° C. (TMA) 193° C. (DMA)

Coefficient of thermal expansion (CTE): 72 ppm/° C. (50° C. to 80° C.)

Tensile strength at break: 60 MPa

Elongation at break: 4.7%

Tensile elasticity: 1.6 GPa

Cut-off wavelength: 319 nm

Transmission at 500 nm: 82%,

Average refractive index (nₐᵥₑ): 1.596 (d line)

Birefringence (Δn): 0.003 (d line)

Dielectric constant (ε) calculated from refractive index: 2.55 (ε=nₐᵥₑ²)

Dielectric constant (Dk): 2.53 (TE mode, 10 GHz), 2.49 (TE mode, 20 GHz)

Dielectric dissipation factor (Df): 0.0011 (TE mode, 10 GHz), 0.0013 (TE mode, 20 GHz)

### Example 16

Synthesis of Fluorine-Containing Polyether (FPPFB-TBISRX)

A polyether was synthesized by performing polymerization at 190° C. for 4 hours using 1,4-bis(4-fluorophenyl)perfluorobutane (FPPFB) in place of FPPFH in Example 12.

Yield of polymer: 79%

Logarithmic viscosity (ηᵢₙₕ): 0.92 dL/g (0.5 g/dL concentration solution in NMP, measured at 30° C.)

Number average molecular weight (Mn): 89,000, Molecular weight distribution (Mw/Mn): 2.4 This polymer was dissolved in chloroform to prepare a colorless transparent cast film (film thickness 42 μm).

FT-IR (film, cm⁻¹): 1602 (C═C), 1510 (C═C), 1284-1154 (C—F), 1104 (C—O)

Elemental analysis (C₄₁H₂₂O₃F₈)
Calculated value C, 68.91%; H, 3.10%
Measured value C, 68.90%; H, 3.15%

Solubility: soluble to NMP, TMU, DMI, DMAc, DMF, THF, chloroform, cyclohexanone, and cyclopentanone

5% Weight loss temperature: 501° C. (in air), 546° C. (in nitrogen)

10% Weight loss temperature: 522° C. (in air), 563° C. (in nitrogen)

Carbonization yield: 64% (in nitrogen, 800° C.)

Glass transition temperature (Tg): 211° C. (DSC), 211° C. (TMA), 210° C. (DMA)

Coefficient of thermal expansion (CTE): 74 ppm/° C. (50° C. to 80° C.)

Tensile strength at break: 59 MPa

Elongation at break: 4.5%

Tensile elasticity: 2.4 GPa

Cut-off wavelength: 312 nm

Transmission at 500 nm: 83%,

Average refractive index (nₐᵥₑ): 1.601 (d line)

Birefringence (Δn): 0.004 (d line)

Dielectric constant (ε) calculated from refractive index: 2.56 (ε=nₐᵥₑ²)

Dielectric constant (Dk): 2.54 (TE mode, 10 GHz), 2.51 (TE mode, 20 GHz)

Dielectric dissipation factor (Df): 0.0010 (TE mode, 10 GHz), 0.0012 (TE mode, 20 GHz)

### Example 17

Synthesis of Fluorine-Containing Polyether (FPPFB-BisPCDE)

A polyether was synthesized by performing polymerization at 190° C. for 5 hours using 1,4-bis(4-fluorophenyl)perfluorobutane (FPPFB) in place of FPPFH in Example 4.

Yield of polymer: 80%

Logarithmic viscosity (ηᵢₙₕ): 0.86 dL/g (0.5 g/dL concentration solution in NMP, measured at 30° C.)

Number average molecular weight (Mn): 85,000, Molecular weight distribution (Mw/Mn): 2.4

This polymer was dissolved in chloroform to prepare a colorless transparent cast film (film thickness 44 μm).

FT-IR (film, cm⁻¹): 2938 (C—H), 2863 (C—H), 1600 (C═C), 1502 (C═C), 1286-1139 (C—F), 1103 (C-0)

Elemental analysis (C₄₀H₃₈O₂F₈):
Calculated value C, 68.36%; H, 5.45%
Measured value C, 68.62%; H, 5.47%

Solubility: soluble to NMP, TMU, DMI, THF, chloroform, cyclohexanone, and cyclopentanone

5% Weight loss temperature: 323° C. (in air), 427° C. (in nitrogen)

10% Weight loss temperature: 337° C. (in air), 440° C. (in nitrogen)

Carbonization yield: 44% (in nitrogen, 800° C.)

Glass transition temperature (Tg): 174° C. (DSC), 172° C. (TMA) 171° C. (DMA)

Coefficient of thermal expansion (CTE): 84 ppm/° C. (50° C. to 80° C.)

Tensile strength at break: 60 MPa

Elongation at break: 5.8%

Tensile elasticity: 1.4 GPa

Cut-off wavelength: 292 nm

Transmission at 500 nm: 84%,

Average refractive index (nₐᵥₑ): 1.547 (d line)

Birefringence (Δn): 0.004 (d line)

Dielectric constant (ε) calculated from refractive index: 2.39 (ε=nₐᵥₑ²)

Dielectric constant (Dk): 2.44 (TE mode, 10 GHz), 2.38 (TE mode, 20 GHz)

Dielectric dissipation factor (Df): 0.0008 (TE mode, 10 GHz), 0.0010 (TE mode, 20 GHz)

### Comparative Example 1

Synthesis of Fluorine-Containing Polyether (FPPFH-BisA)

In a two-necked flask (50 mL) equipped with a stirring bar, a nitrogen introducing tube, a Dean-Stark trap, and a Dimroth condenser, FPPFH (0.981 g, 2.0 mmol) and 2,2-bis(4-hydroxyphenyl)propane (BisA, 0.457 g, 2.0 mmol) were placed and dissolved in distilled 1,3-dimethyl-2-imidazolidone (DMI, 5.0 mL). Thereafter, potassium carbonate (0.332 g, 2.4 mmol) and toluene (20 mL) were added thereto. The temperature of the resultant mixture was increased in stages to 150° C., and the mixture was then stirred at 150° C. for 2 hours to remove water by azeotropy. Thereafter, the mixture was stirred at 170° C. for 12 hours. After the mixture was left standing to cool to room temperature, a polymer was collected with methanol. The polymer was cleaned with methanol while heating, and then dried under reduced pressure at room temperature. The polymer was dissolved in chloroform, and the resultant solution was poured into a large amount of methanol to purify the polymer by reprecipitation. The polymer was dried under reduced pressure at room temperature for 10 hours.

Yield of polymer: 1.15 g (80%)

Logarithmic viscosity (ηᵢₙₕ): 0.71 dL/g (0.5 g/dL concentration solution in NMP, measured at 30° C.)

Number average molecular weight (Mn): 75,000, Molecular weight distribution (Mw/Mn): 2.5

This polymer was dissolved in chloroform, and the resultant solution was cast onto a glass plate and dried at room temperature for 6 hours, subsequently at 50° C. for 3 hours, and then under reduced pressure at 85° C. for 3 hours to prepare a colorless transparent cast film (film thickness 52 μm).

FT-IR (film, cm⁻¹): 2937 (C—H), 2862 (C—H), 1600 (C═C), 1504 (C═C), 1292-1143 (C—F)

¹H-NMR (CDCl₃, ppm): 7.51 (d, 4H), 7.26 (d, 4H), 7.05 (d, 4H), 6.98 (d, 4H), 1.70 (s, 6H)

¹³C-NMR (CDCl₃, ppm): 161.0, 153.5, 146.9, 128.8, 128.5, 123.2, 119.7, 117.7, 42.5, 31.1

¹⁹F-NMR (CDCl₃, ppm): −111.0, −122.6, −123.1

### Elemental Analysis:

Calculated value C, 58.41%; H, 3.27%
Measured value C, 57.90%; H, 3.34%

Solubility: soluble to DMF, DMAc, NMP, TMU, DMI, THF, chloroform, ethyl acetate, cyclohexanone, and cyclopentanone at room temperature

5% Weight loss temperature: 443° C. (in air), 504° C. (in nitrogen)

10% Weight loss temperature: 458° C. (in air), 511° C. (in nitrogen)

Carbonization yield: 46% (in nitrogen, 800° C.)

Glass transition temperature (Tg): 93° C. (DSC), 96° C. (TMA), 93° C. (DMA)

Coefficient of thermal expansion (CTE): 94 ppm/° C. (50° C. to 80° C.)

Tensile strength at break: 35 MPa

Elongation at break: 3.4%

Tensile elasticity: 1.3 GPa

Cut-off wavelength: 290 nm

Transmission at 500 nm: 88%,

Average refractive index (nₐᵥₑ): 1.531 (d line)

Birefringence (Δn): 0.001 (d line)

Dielectric constant (ε) calculated from refractive index: 2.34 (ε=nₐᵥₑ²)

Dielectric constant (Dk): 2.42 (TE mode, 10 GHz), 2.35 (TE mode, 20 GHz)

Dielectric dissipation factor (Df): 0.0025 (TE mode, 10 GHz), 0.0027 (TE mode, 20 GHz)

### Comparative Example 2

Synthesis of Fluorine-Containing Polyether (FPPFH-BisAF)

In a two-necked flask (50 mL) equipped with a stirring bar, a nitrogen introducing tube, a Dean-Stark trap, and a Dimroth condenser, FPPFH (0.981 g, 2.0 mmol) and 2,2-bis(4-hydroxyphenyl)hexafluoropropane (BisAF, 0.673 g, 2.0 mmol) were placed and dissolved in distilled 1,3-dimethyl-2-imidazolidone (DMI, 5.0 mL). Thereafter, potassium carbonate (0.332 g, 2.4 mmol) and toluene (20 mL) were added thereto. The temperature of the resultant mixture was increased in stages to 150° C., and the mixture was then stirred at 150° C. for 2 hours to remove water by azeotropy. Thereafter, the mixture was stirred at 170° C. for 12 hours. After the mixture was left standing to cool to room temperature, a polymer was collected with methanol. The polymer was cleaned with methanol while heating, and then dried under reduced pressure at room temperature. The polymer was dissolved in chloroform, and the resultant solution was poured into a large amount of methanol to purify the polymer by reprecipitation. The polymer was dried under reduced pressure at room temperature for 10 hours.

Yield of polymer: 1.14 g (69%)

Logarithmic viscosity (ηᵢₙₕ): 0.73 dL/g (0.5 g/dL concentration solution in NMP, measured at 30° C.)

Number average molecular weight (Mn): 73,000, Molecular weight distribution (Mw/Mn): 2.6

This polymer was dissolved in chloroform, and the resultant solution was cast onto a glass plate and dried at room temperature for 6 hours, subsequently at 50° C. for 3 hours, and then under reduced pressure at 85° C. for 3 hours to prepare a colorless transparent cast film (film thickness 57 μm).

FT-IR (film, cm⁻¹): 1600 (C═C), 1504 (C═C), 1292-1143 (C—F)

¹H-NMR (CDCl₃, ppm): 7.58 (d, 4H), 7.41 (d, 4H), 7.13 (d, 4H), 7.04 (d, 4H)

¹³C-NMR (CDCl₃, ppm): 159.6, 156.8, 132.1, 129.1, 129.0, 124.4, 124.3, 119.0

¹⁹F-NMR (CDCl₃, ppm): −65.4, −111.2, −122.7, −123.3

### Elemental Analysis:

Calculated value C, 50.40%; H, 2.05%
Measured value C, 50.37%; H, 2.18%

Solubility: soluble to DMF, DMAc, NMP, TMU, DMI, THF, chloroform, ethyl acetate, cyclohexanone, cyclopentanone, and acetone at room temperature

5% Weight loss temperature: 505° C. (in air), 507° C. (in nitrogen)

10% Weight loss temperature: 524° C. (in air), 519° C. (in nitrogen)

Carbonization yield: 42% (in nitrogen, 800° C.)

Glass transition temperature (Tg): 95° C. (DSC), 105° C. (TMA), 97° C. (DMA)

Coefficient of thermal expansion (CTE): 105 ppm/° C. (50° C. to 80° C.)

Tensile strength at break: 34 MPa

Elongation at break: 3.8%

Tensile elasticity: 1.2 GPa

Cut-off wavelength: 282 nm

Transmission at 500 nm: 89%,

Average refractive index (nₐᵥₑ): 1.500 (d line)

Birefringence (Δn): 0.004 (d line)

Dielectric constant (ε) calculated from refractive index: 2.25 (ε=nₐᵥₑ²)

Dielectric constant (Dk): 2.15 (TE mode, 10 GHz), 2.13 (TE mode, 20 GHz)

Dielectric dissipation factor (Df): 0.0042 (TE mode, 10 GHz), 0.0043 (TE mode, 20 GHz)

1. A fluorine-containing polyether compound comprising a repeating unit represented by formula (1): 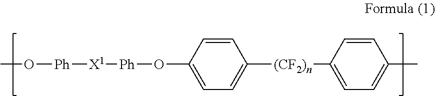
in formula (1), n represents an integer of 4 to 8, Ph represents a phenylene group, and X¹ represents a heterocyclic ring or a hydrocarbon ring; one or both of two phenylene groups represented by Ph, and the heterocyclic ring or the hydrocarbon ring represented by X¹ are optionally condensed with each other; and the phenylene group, the heterocyclic ring, and the hydrocarbon ring optionally have a substituent.

2. The fluorine-containing polyether compound according to claim 1, wherein X¹ represents an aromatic heterocyclic ring optionally having a substituent, an aromatic hydrocarbon ring optionally having a substituent, or an aliphatic hydrocarbon ring optionally having a substituent.

3. The fluorine-containing polyether compound according to claim 1, wherein X¹ represents at least one selected from the group consisting of rings represented by the following formulas: 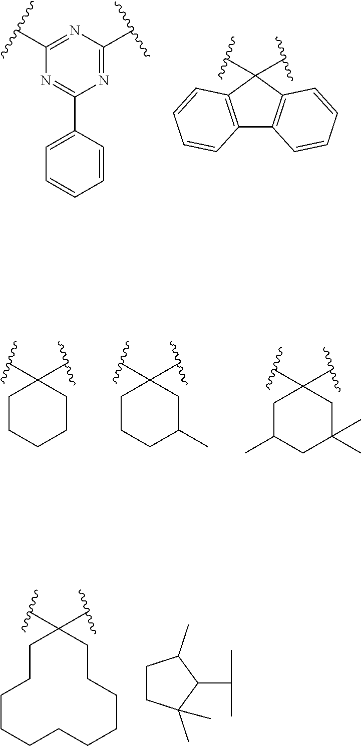
in each formula, each undulating line represents a bond position to the phenylene group represented by Ph, and a broken line represents a carbon-carbon bond shared with the phenylene group represented by Ph.

4. The fluorine-containing polyether compound according to claim 1, wherein an average degree of polymerization of the repeating unit represented by formula (1) is 2 to 300.

5. A fluorine-containing polyether compound consisting of a repeating unit represented by formula (2): 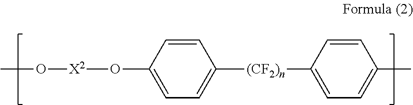
in formula (2), n represents an integer of 1 to 8, and X² represents a polycyclic aromatic hydrocarbon ring optionally having a substituent.

6. The fluorine-containing polyether compound according to claim 5, wherein the polycyclic aromatic hydrocarbon ring is at least one selected from the group consisting of a biphenyl ring, a terphenyl ring, a quaterphenyl ring, a naphthalene ring, an anthracene ring, a tetracene ring, and a pentacene ring.

7. The fluorine-containing polyether compound according to claim 5, wherein an average degree of polymerization of the repeating unit represented by formula (2) is 2 to 300.

8. A low dielectric material comprising the fluorine-containing polyether compound according to claim 1.

9. A semiconductor package substrate, a flexible printed circuit board, or a rigid printed circuit board comprising the fluorine-containing polyether compound according to claim 1.

10. A low dielectric material comprising the fluorine-containing polyether compound according to claim 5.

11. A semiconductor package substrate, a flexible printed circuit board, or a rigid printed circuit board comprising the fluorine-containing polyether compound according to claim 5.
